(19) United States
(12) Patent Application Publication
(10) Pub. No.: US 2009/0173947 A1
(43) Pub. Date: Jul. 9, 2009

(54) DISPLAY SUBSTRATE AND DISPLAY PANEL HAVING THE SAME

(75) Inventor: Dong-Gyu KIM, Yongin-si (KR)

Correspondence Address: CANTOR COLBURN, LLP, 20 Church Street, 22nd Floor, Hartford, CT, 06103, US

(73) Assignee: SAMSUNG ELECTRONICS CO., LTD, Suwon-si (KR)

(21) Appl. No.: 12/241,756

(22) Filed: Sep. 30, 2008

(30) Foreign Application Priority Data
Jan. 4, 2008 (KR) 2008-1239

(51) Int. Cl. H01L 29/04; G02F 1/1335

(52) U.S. Cl. 257/72; 349/106; 257/E29.003

(57) ABSTRACT

A display substrate according to exemplary embodiments of the present invention includes a transistor layer, a color filter layer and a pixel electrode. The transistor layer includes a transistor connected to a gate line and a data line crossing each other, and a contact part extending from a drain electrode of the transistor. The color filter layer is disposed on the transistor layer. The color filter layer has an opening formed therein, and a center of the opening is spaced apart from a center of the contact part. The pixel electrode is electrically connected to the transistor through a contact hole exposing the contact part.

This application claims priority to Korean Patent Application No. 2008-1239, filed on Jan. 4, 2008, and all the benefits accruing therefrom under 35 U.S.C. § 119, the contents of which in their entirety are herein incorporated by reference.

### BACKGROUND OF THE INVENTION

1. Field of the Invention

The present invention relates to a display substrate and a display device having the display substrate. More particularly, the present invention relates to a an array substrate having a color filter layer used for a display device and a display device having the array substrate having the color filter layer.

2. Description of the Related Art

Generally, a liquid crystal display (“LCD”) panel includes an array substrate including a plurality of thin-film transistors (TFTs), a color filter substrate facing the array substrate and including a plurality of color filters, and a liquid crystal layer disposed between the array substrate and the color filter substrate.

Recently, a color filter on array (“COA”) substrate which includes a color filter on an array substrate has been developed. The COA substrate includes a transistor layer formed on a base substrate, a color filter layer formed on the transistor layer and a pixel electrode formed on the color filter layer.

Thus, the color filter layer is formed on the array substrate including the transistor layer so that a manufacturing process of the color filter substrate is simplified. The color filter layer having a thickness of about 2 micrometers (μm) to about 3 μm is formed between a data line formed in the transistor layer and the pixel electrode, so that a capacitance between the data line and the pixel electrode may be decreased. Thus, the pixel electrode may be formed to overlap the data line so that an aperture ratio of the LCD panel may be improved.

### BRIEF SUMMARY OF THE INVENTION

The present disclosure provides a display substrate capable of improving light transmittance.

The present disclosure further provides a display panel having the display substrate.

A display substrate according to an exemplary embodiment of the present invention includes a transistor layer, a color filter layer and a pixel electrode. The transistor layer includes a transistor connected to a gate line and a data line crossing each other, and a contact part extending from a drain electrode of the transistor. The color filter layer is disposed on the transistor layer and the color filter layer defines an opening, and a center of the opening is spaced apart from a center of the contact part. The pixel electrode is connected to the transistor through a contact hole exposing the contact part.

The transistor is adjacent to a portion at which the gate line crosses the data line, and the contact part is adjacent to the transistor. Each of the contact part and the opening comprise four sides. Upper and left sides of the opening are spaced apart from upper and left sides of the contact part, so that the upper and left sides of the opening are disposed in an area corresponding to the contact part. Lower and right sides of the opening are spaced apart from lower and right sides of the contact part and are outside of the area corresponding to the contact part. The contact hole is formed in an area in which the contact part overlaps the opening.

The display substrate further comprises a light-blocking layer disposed under the data line, and the light-blocking layer has a floating state. The light-blocking layer is formed from the same layer as the gate line. The pixel electrode is spaced apart from the data line.

A display panel according to an exemplary embodiment of the present invention includes a display substrate and an opposing substrate. The display substrate includes a transistor layer including a transistor connected to a gate line and a data line crossing the gate line, and a contact part extending from a drain electrode of the transistor, a color filter layer disposed on the transistor layer, the color filter layer having an opening, a center of the opening is spaced apart from a center of the contact part, and a pixel electrode connected to the transistor through a contact hole exposing the contact part. The opposing substrate couples with the display substrate to receive a liquid crystal layer therebetween, and the opposing substrate includes a common electrode.

The liquid crystal layer includes liquid crystal having a high driving voltage and a low dielectric anisotropy. The transistor is adjacent to an area in which the gate line crosses the data line, and the contact part is adjacent to the transistor.

Each of the contact part and the opening comprise four sides. Upper and left sides of the opening are spaced apart from upper and left sides of the contact part. The upper and left sides of the opening are defined in an area corresponding to the contact part. Lower and right sides of the opening are spaced apart from lower and right sides of the contact part, and the lower and right sides of the opening are outside of area corresponding to the contact part. The contact hole is disposed in an area overlapping the contact part and the opening.

The opposing substrate further includes a blocking pattern which blocks light. The blocking pattern exposes the upper and left sides of the contact part and covers the opening. The display substrate further includes a light-blocking layer disposed under the data line, and the light-blocking layer has a floating state. The light-blocking layer is formed from the same layer as the gate line.

According to the display substrate and the display panel having the display substrate, the opening is formed in the area in which the contact part is formed. The upper and left sides of the opening are defined in the area corresponding to the contact part, and are spaced apart from the upper and left sides of the contact part. Therefore, light leakage from a stepped portion of the opening may be prevented using the contact part. In addition, a size of the contact part may be reduced to improve light transmittance.

### BRIEF DESCRIPTION OF THE DRAWINGS

The above and other aspects, features and advantages of the present invention will become more apparent by describing in more detail exemplary embodiments thereof with reference to the accompanying drawings, in which:

FIG. 1 is a plan view illustrating a display panel according to a first exemplary embodiment of the present invention;

FIG. 2 is a cross-sectional view taken along line I-I′ in FIG. 1; and

FIGS. 3A and 3B are plan views partially illustrating various shapes of a contact part and an opening in FIG. 1;

FIGS. 4A to 4D are cross-sectional views illustrating processes for manufacturing the display substrate shown in FIG. 2;

FIG. 5 is a plan view partially illustrating a display panel according to a second exemplary embodiment of the present invention; and

FIG. 6 is a cross-sectional view taken along line II-II′ in FIG. 5.

### DETAILED DESCRIPTION OF THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in more detail with reference to the accompanying drawings.

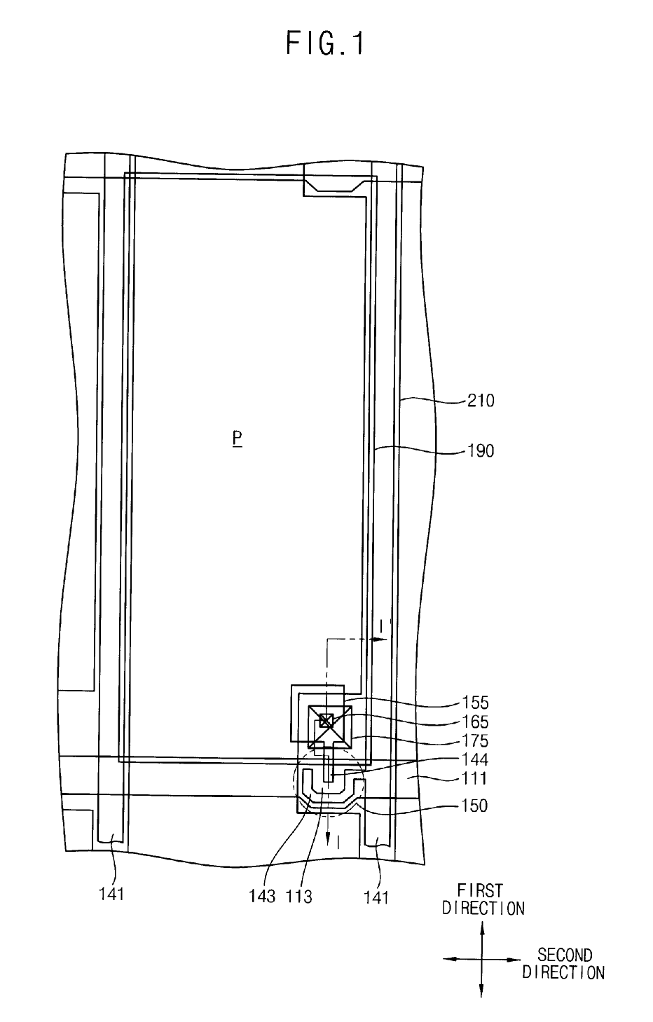

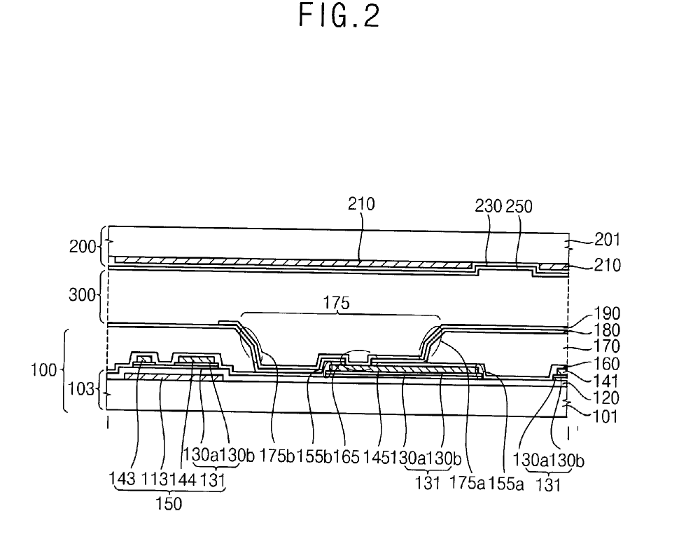

FIG. 1 is a plan view illustrating a display panel according to a first embodiment of the present invention. FIG. 2 is a cross-sectional view taken along line I-I′ in FIG. 1.

Referring to FIGS. 1 and 2, a display panel includes a display substrate 100, an opposing substrate 200 and a liquid crystal layer 300 disposed between the display substrate 100 and the opposing substrate 200.

The display substrate 100 includes a first base substrate 101, a transistor layer 103, a color filter layer 170, a capping layer 180 and a pixel electrode 190. The display substrate 100 has a structure which does not have a metal pattern of a storage common electrode of a storage capacitor. For example, the display substrate 100 does not have a storage common line formed in a plurality of pixel areas, and does not have a storage electrode independently formed on each of the pixel areas.

The transistor layer 103 includes a gate line 111, a data line 141, a transistor 150 and a contact part 155. The gate line 111 extends in a first direction, and is formed on the first base substrate 101. The data line 141 extends in a second direction crossing the first direction, and is formed on the first base substrate 101.

The transistor 150 is adjacent to an area in which the gate line 111 crosses the data line 141. The transistor 150 includes a gate electrode 113, a semiconductor pattern 131, a source electrode 143 and a drain electrode 144. The gate electrode 113 is connected to a portion of the gate line adjacent to the area in which the gate line 111 crosses the data line 141. In FIGS. 1 and 2, a portion of the gate line 111 may be defined as the gate electrode 113. Alternatively, the gate electrode 113 may protrude from the gate line 111. The semiconductor pattern 131 includes an active layer 130a doped with impurities and an ohmic contact layer 130b. The source electrode 143 extends to the gate electrode 113 from the data line 141 to overlap the semiconductor pattern 131. For example, the source electrode 143 has a U-shape, as illustrated in FIG. 1. The drain electrode 144 is spaced apart from the source electrode 143, and overlaps the semiconductor pattern 131, as illustrated in FIG. 2.

The contact part 155 is electrically connected to the drain electrode 144, and is formed in a pixel area defined on the first base substrate 101. The contact part 155 is adjacent to the transistor 150. For example, the contact part 155 is integrated with an end portion of the drain electrode 144, and is adjacent to the data line 141. Thus, a contact hole 165 electrically connecting the pixel electrode 190 with the transistor 150 is formed on the contact part 155.

The transistor layer 103 may further include a gate insulating layer 120 formed on the gate line 113 and the gate electrode 113, and a protecting layer 160 formed on the data line 141, the source electrode 143 and the drain electrode 144.

Here, a semiconductor layer and a source metal layer are patterned using one mask, so that the semiconductor patterns 131 are formed under the data line 141, the source electrode 143, the drain electrode 144 and the contact part 155 using the source metal layer as an etching mask.

The color filter layer 170 is formed on the transistor layer 103. An opening 175 is formed at the color filter layer 170. A center of the opening 175 and a center of the contact part 155 cross each other, and a size of the opening 175 is smaller than a size of the contact part 155, as illustrated in FIG. 1.

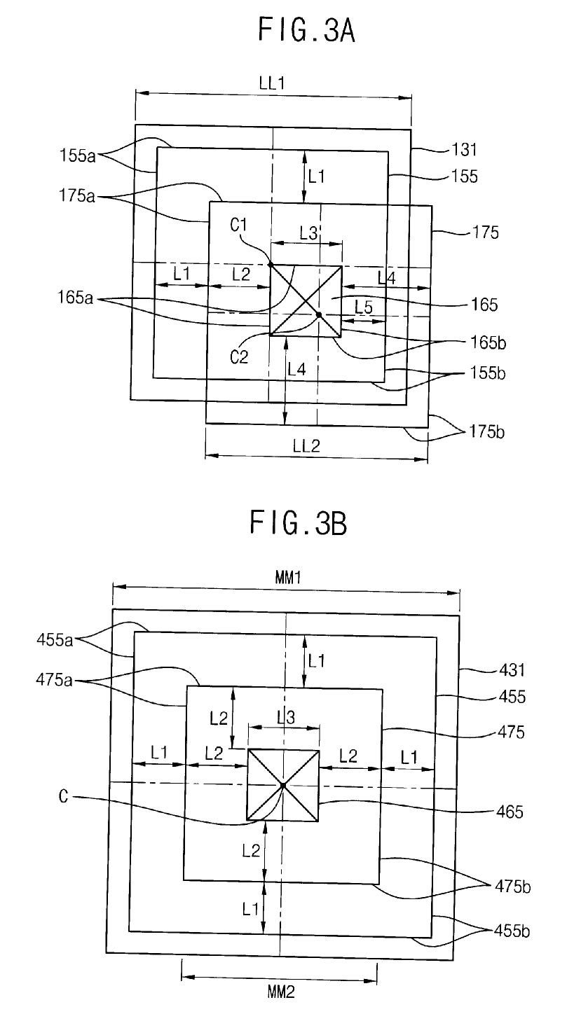

For example, each of the contact part 155 and the opening 175 has four sides. Referring to FIG. 1 and FIG. 3A, upper and left sides 175a of the opening 175 are spaced apart from upper and left sides 155a of the contact part 155, and the upper and left sides 175a of the opening 175 are defined in an area corresponding to the contact part 155. Lower and right sides 175b of the opening 175 are spaced apart from lower and right sides 155b of the contact part 155, and are disposed out of the area corresponding to the contact part 155. Therefore, light leaked from a stepped portion formed by the upper and left sides 175a of the opening 175 may blocked by using the contact part 155. An arrangement of the liquid crystal varies at the stepped portion so that the light may be leaked through the liquid crystal at the stepped portion. However, the contact part 155 blocks the leaked light having passed through the stepped portion.

The light which leaks from the stepped portion formed by the lower and right sides 175b of the opening 175 may be blocked by using a blocking pattern 210 of the opposing substrate 200.

The capping layer 180 is formed on the color filter layer 170 to cover the color filter layer 170. The capping layer 180 blocks impurity ions from entering the liquid crystal layer 300. The impurity ions may be generated from the color filter layer 170.

The contact hole 165 is formed through the protecting layer 160 and the capping layer 180. The contact hole 165 is formed on an area in which the opening 175 is overlapped with the contact part 175 to expose the contact part 155.

The pixel electrode 190 is contacted to the contact part 155 through the contact hole 165, and the pixel electrode 190 is formed in the pixel area P (see FIG. 1). The pixel electrode 190 may have open patterns which divide the liquid crystal layer 300 into a plurality of domains to form a multi-domain structure. An end of the pixel electrode 190 partially overlaps the data line 141.

The opposing substrate 200 includes a second substrate 201, a blocking pattern 210, an overcoating layer 230 and a common electrode 250.

The blocking pattern 210 blocks light, and the blocking pattern 210 is formed on the second substrate 201 except at an area in which the pixel electrode 190 is formed. For example, the blocking pattern 210 is formed on the second substrate 201 corresponding to an area in which the data line 141, the transistor 150 and the opening 175 are formed. In addition, the blocking pattern 210 may be further formed on the second substrate 201 corresponding to an area in which the gate line 111 is formed.

The blocking pattern 210 exposes the upper and left sides 155a of the contact part 155, and the blocking pattern 210 covers the opening 175, as illustrated in FIG. 2. Thus, light leaked from a stepped portion formed by four sides of the opening 175 may be blocked. Therefore, the light leaked from the stepped portion formed by the upper and left sides 175a of the opening 175 may be blocked using the contact part 155. An arrangement of the liquid crystal varies at the stepped portion so that the light may be leaked through the tilted liquid crystal. However, the light leaked from the stepped portion formed by the lower and right sides 175b of the opening 175 may be blocked by using the blocking pattern 210 of the opposing substrate 200.

The overcoating layer 230 is formed on the second substrate 201 on which the blocking pattern 210 is formed, and the overcoating layer 230 planarizes the surface of the opposing substrate 200.

The common electrode 250 is formed on the second substrate 201 on which the overcoating layer 230 is formed. The common electrode 250 may have open patterns which divide the liquid crystal layer 300 into the plurality of domains to form the multi-domain structure.

The liquid crystal layer 300 is disposed between the display substrate 100 and the opposing substrate 200. The liquid crystal layer 300 includes the liquid crystal which has various characteristics such as a low driving voltage, a low dielectric anisotropy, etc. Alternatively, the liquid crystal may have a high driving voltage.

For example, when the liquid crystal having the low driving voltage and the high dielectric anisotropy is employed in laptop computers having the display panel without the storage capacitor, a response speed of the liquid crystal may be decreased. However, when the liquid crystal having the high driving voltage and the low dielectric anisotropy is employed in the laptop computers having the display panel, the response speed of the liquid crystal may not be changed even though the display panel does not have the storage capacitor.

Therefore, in exemplary embodiments of the present invention, the liquid crystal layer 300 may be employed in the display substrate 100 without the storage electrode or the storage common line, and the liquid crystal may have the high driving voltage and the low dielectric anisotropy, thereby increasing the response speed of the liquid crystal.

FIGS. 3A and 3B are plan views partially illustrating various shapes of the contact part 155 and the opening 175 in FIG. 1.

Referring to FIGS. 1, 2 and 3A, the contact part 155 has the upper, lower, left and right sides 155a and 155b. The opening 175 has the upper, lower, left and right sides 175a and 175b. The contact hole 165 has upper, lower, left and right sides 165a and 165b.

The opening 175 is formed on the contact part 155 so that a center C2 of the opening 175 is disposed on an area spaced apart from a center C1 of the contact part 155. The contact hole 165 is formed on an area in which the contact part 155 overlaps with the opening 175.

The upper and left sides 175a of the opening 175 are spaced apart from the upper and left sides 155a of the contact part 155 by a length L1, respectively. The L1 may be about 2 μm to about 71β. Thus, the light leaked from a stepped portion formed by the upper and left sides 175a of the opening 175 may be blocked using the contact part 155. The contact hole 165 is spaced apart from the upper and left sides 175a of the opening 175 by a length L2, respectively. The L2 may be about 2 μm to about 7 μm. A width of the contact hole 165 has a length L3. The L3 may be about 4 μm to about 8 μm.

The lower and right sides 165b of the contact hole 165 are spaced apart from the lower and right sides 175b of the opening 175 by a length L4, respectively. The L4 may be about 4 μm to about 10 μm. The lower and right sides 175b of the opening 175 are spaced apart from the lower and right sides 155b of the contact part 155. The lower and right sides 165b of the contact hole 165 are spaced apart from the lower and right sides 155b of the contact part 155 by a length L5, respectively. The L5 maybe about 2 μm to about 5 μm.

Therefore, the upper side of the contact part 155 has a length LL1 that is approximately a sum of L1, L2, L3 and L5. The LL1 may be about 10 μm to about 3 μm. The upper side of the opening 175 has a length LL2 that is approximately a sum of L2, L3 and L4. The LL2 may be about 10 μm to about 25 m.

For example, the L1 is about 6 μm, L2 is about 7 μm, L3 is about 8 μm, L4 is about 10 μm and L5 is about 5 μm. When the semiconductor pattern 131 is formed under the contact part 155, the length LL1 of the upper side of the contact part 155 maybe about 28 μm. The length LL2 of the upper side of the opening 175 may be about 25 μm. A distance between an end of the semiconductor pattern 131 and an end of the contact part 175 may be about 01 m to about 2 μm.

Referring to FIG. 3B illustrating another shape of a contact part and an opening in FIG. 1, each of a contact part 455, an opening 475 and a contact hole 465 has four sides. Centers of the contact part 455, the opening 475 and the contact hole 465 are accurately spaced apart by the same area. The opening 475 is spaced apart from the four sides 455a and 455b of the contact part 455 by a length L1 to be disposed in an area in which the contact part 455 is formed. Light leaked from a stepped portion of the color filter may be blocked using the contact part 455.

The contact hole 465 is spaced apart from the four sides 475a and 475b by a length L2, respectively. The contact hole 465 has a width being the same as a length L3.

Therefore, the upper side of the contact part 455 has a length MM1 which is approximately a sum of L1, L2, L3, L2 and L1. The upper side of the opening 475 has a length MM2 that is approximately a sum of L2, L3 and L2. For example, the L1 is about 6 μm, L2 is about 7 μm and L3 is about 8 μm. When the semiconductor pattern 131 is formed under the contact part 455, the length MM1 of the upper side of the contact part 455 may be about 36 μm. The length MM2 of the upper side of the opening 475 may be about 23 μm.

The length LL1 of upper side of the contact part 155 in FIG. 3A is smaller by about 8 μm than the length MM1 of upper side of the contact part 455 in FIG. 3B. Thus, the size of the contact part 155 may be reduced, so that the light transmittance and aperture ratio of the display substrate 100 may be improved.

In FIG. 3A, the display substrate 100 according to the first embodiment includes the contact part 155 and the opening 175, and the display substrate 100 dose not have the storage common line or the storage electrode in the pixel area P.

Therefore, the display substrate 100 according to the first embodiment may improve light transmittance by about 18% compared to the display substrate which includes the contact part 455 and the opening 475 shown in FIG. 3B, and the storage common line or the storage electrode formed in the pixel area P

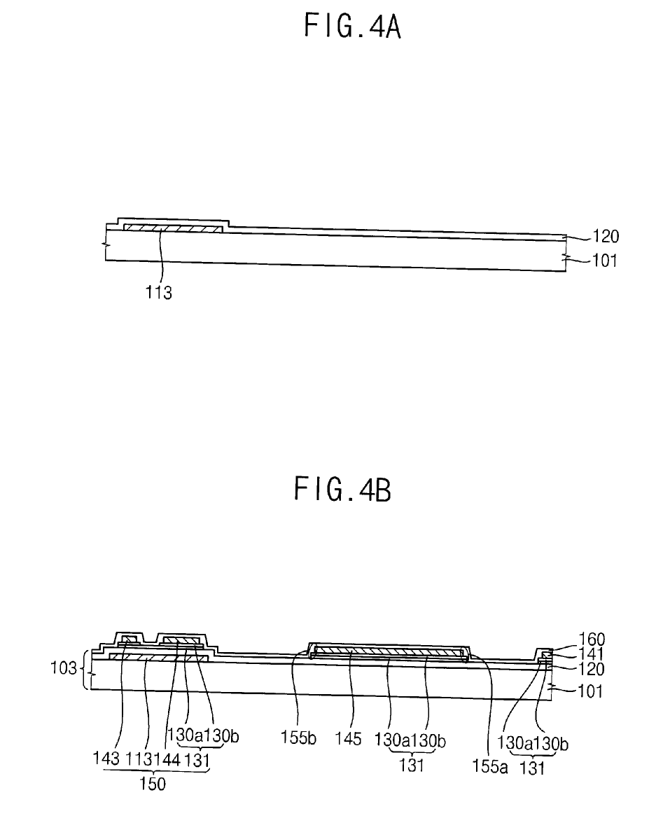

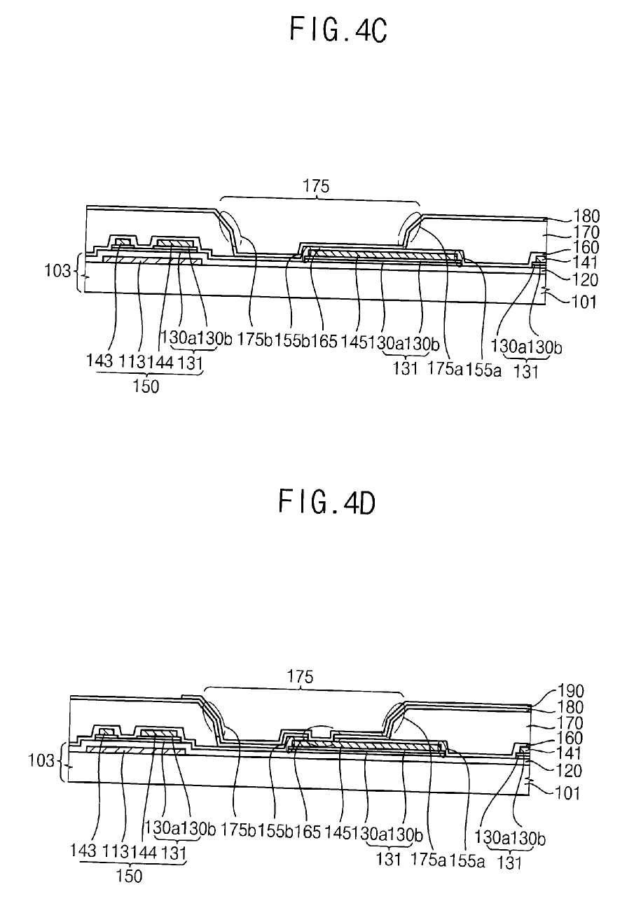

FIGS. 4A to 4D are cross-sectional views illustrating a method for manufacturing the display substrate shown in FIG. 2.

Referring to FIGS. 1 and 4A, a gate metal layer is formed on the base substrate 101. The gate metal layer is patterned using a photoresist mask to form a gate metal pattern. A gate metal pattern includes a gate line 111 and a gate electrode 113. A gate insulating layer 120 is formed on the base substrate 101 having the gate metal pattern formed thereon.

Referring to FIGS. 1 and 4B, a semiconductor layer and a source metal layer are sequentially formed on the base substrate 101 having the gate insulating layer 120 formed thereon. The semiconductor layer includes an active layer 130a doped with impurities and an ohmic contact layer 130b.

The source metal layer and the semiconductor layer are patterned using a photoresist mask to form a source metal pattern and a semiconductor pattern 131 under the source metal pattern. The source metal pattern includes the data line 141, the source electrode 143, the drain electrode 144 and the contact part 155. The contact part 155 extends from the end portion of the drain electrode 144 to be formed adjacent to the area in which the gate line 111 crosses the data line 141.

The protecting layer 160 is formed on the base substrate 101 having the source metal pattern formed thereon to complete the transistor layer 103.

Referring to FIGS. 1, 2 and 4C, a color organic layer is formed on the base substrate 101 having the transistor layer 103 formed thereon. The color organic layer has a thickness of about 2 μm to about 3 μm. The color organic layer is patterned using a mask which has a transmitting part which transmits light and a blocking part which blocks light to form the color filter layer 170 in pixel area P. The opening 175 is formed at the color filter layer 170 and the opening 175 exposes the protecting layer 160 corresponding to the contact part 155.

The upper and left sides 175a of the opening 175 are spaced apart form the upper and left sides 155a of the contact part 155 and inside an area corresponding to the contact part 155. The lower and right sides 175b of the opening 175 are spaced apart from the lower and right sides 155b of the contact part 155 and are outside of the area corresponding to the contact part 155.

Each of the upper, left, lower and right sides 175a and 175b of the opening 175 has a stepped portion. An arrangement of the liquid crystal varies at the stepped portion so that light may be leaked through the liquid crystal at the stepped portion.

Therefore, the light that leaks from the stepped portion formed by the upper and left sides 175a of the opening 175 may be blocked using the contact part 155. The arrangement of the liquid crystal varies at the stepped portion so that the light may be leaked through the liquid crystal at the stepped portion. The light leaked from the stepped portion formed by the lower and right sides 175b of the opening 175 may be blocked using a blocking pattern 210 of the opposing substrate 200.

A capping layer 180 is formed on the base substrate 101 having the color filter layer 170 formed thereon, and the capping layer 180 covers an upper surface and a side surface of the color filter layer 170.

Referring to FIGS. 1 and 4D, the capping layer 180 and the protecting layer 160 are etched to form the contact hole 165 exposing the contact part 155. The contact hole 165 is formed in the area in which the contact part 155 overlaps the opening 175.

A transparent conductive layer is formed on the base substrate 101 having the contact hole 165 formed thereon. The transparent conductive layer is patterned using a photoresist mask to form the pixel electrode 190 in pixel area P. The pixel electrode 190 contacts the contact part 155 through the contact hole 165. Thus, the drain electrode 144 of the transistor 150 is electrically connected to the pixel electrode 190. The data line 141 partially overlaps the end of the pixel electrode 190.

Hereinafter, the same reference numerals will be used to refer to the same or like parts as those described in the first embodiment and any further repetitive explanation concerning the above elements will be omitted.

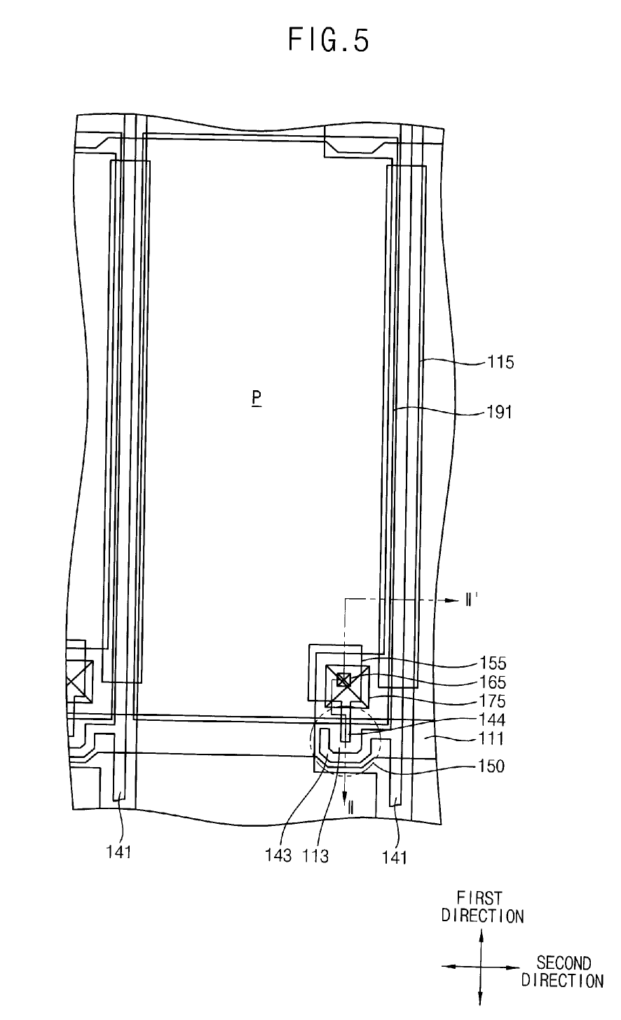

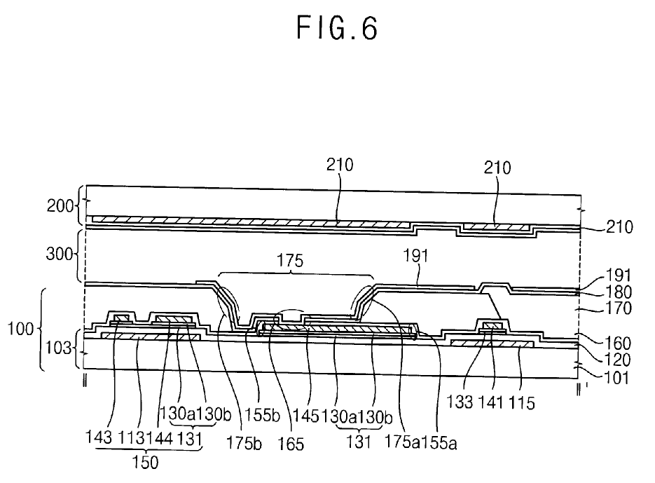

FIG. 5 is a plan view partially illustrating a display panel according to a second embodiment of the present invention. FIG. 6 is a cross-sectional view taken along a line II-II′in FIG. 5.

Referring to FIGS. 5 and 6, the display substrate 100b includes a first base substrate 101, a transistor layer 103, a color filter layer 170, a capping layer 180 and a pixel electrode 191. The display substrate 100b has a structure that does not have a metal pattern of a storage common electrode of a storage capacitor. For example, the display substrate 100b does not have a storage common line formed in a plurality of pixel areas, and does not have a storage electrode independently formed on each of pixel areas.

The transistor layer 103 includes a gate line 111, a light-blocking layer 115, a data line 141, a transistor 150 and a contact part 155.

The light-blocking layer 115 is formed under the data line 141 and to overlap the data line 141. The light-blocking layer 115 is electrically floated and the light-blocking layer 115 blocks light leakage. Thus, the pixel electrode 191 may be formed to be spaced apart from the data line 141 so that the capacitance between the data line 141 and the pixel electrode 191 may be decreased by about 30% to about 40%. The light-blocking layer 115 is electrically floated to decrease the capacitance between the light-blocking layer 115 and the data line 141. For example, the display substrate 100b having the light-blocking layer 115 may be employed in large monitors which are greater than 24 inches.

The contact part 155 is electrically connected to the drain electrode 144 of the transistor 150. The contact part 155 is formed in the pixel area P (FIG. 5) defined on the base substrate 101. For example, the contact part 155 is integrated with an end portion of the drain electrode 144, and is adjacent to the data line 141. A contact hole 165 is formed on the contact part 155 so that the pixel electrode 191 is electrically connected to the transistor 150 through the contact hole 165. The contact hole 165 may be formed using the manufacturing process as that described with respect to FIG. 4D.

The transistor layer 103 may further include a gate insulating layer 120 formed on the gate line 113, the light-blocking layer 115 and the gate electrode 120, and a protecting layer 160 formed on the data line 141, the source electrode 143 and the drain electrode 144.

The color filter layer 170 is formed on the transistor layer 103. An opening 175 is formed at the color filter layer 170. A center of the opening 175 and a center of the contact part 155 are aligned or cross each other, and a size of the opening 175 is smaller than a size of the contact part 155.

For example, each of the contact part 155 and the opening 175 has four sides. Upper and left sides 175a of the opening 175 are spaced apart from the upper and left sides 155a of the contact part 155, and the upper and left sides 175a of the opening 175 are defined in an area corresponding to the contact part 155. Lower and right sides 175b of the opening 175 are spaced apart from lower and right sides 155b of the contact part 155, and the lower and right sides 175b of the opening 175 are defined outside of the area corresponding to the contact part 155.

Therefore, light which leaks from a stepped portion formed by the upper and left sides 175a of the opening 175 may be blocked using the contact part 155. An arrangement of the liquid crystal varies at the stepped portion so that the light may be leaked through the liquid crystal at the stepped portion. However, the contact part 155 blocks the leaked light having passed through the stepped portion.

The light which leaks from a stepped portion formed by the lower and right sides 175b of the opening 175 may be blocked using the blocking pattern 210 of the opposing substrate 200. The capping layer 180 is formed on the color filter layer 170.

The pixel electrode 191 is formed to be spaced apart from the data line 141. The light-blocking layer 115 is formed under the data line 141 to block light leakage from an area between the pixel electrode 191 and the data line 141. Thus, the pixel electrode 191 may be formed to be spaced apart from the data line 141.

Referring to FIGS. 4A to 6, the method of manufacturing according to the second embodiment is described. Hereinafter, the same method of manufacturing as that described in the first embodiment will be omitted and briefly described.

Referring to FIGS. 4A, 5 and 6, the gate metal pattern is formed on the base substrate 101. The gate metal pattern includes the gate line 111, the gate electrode 113 and the light-blocking layer 115.

Referring to FIGS. 4B, 5 and 6, the gate insulating layer 120 is formed on the gate metal pattern having the light-blocking layer 115. The semiconductor layer and the source metal layer are sequentially formed on the base substrate 101 having the gate insulating layer 120 formed thereon. The source metal layer and the semiconductor layer are patterned to form the source metal patterns 141, 143, 144 and 155 and the semiconductor pattern 131 under the source metal pattern. The protecting layer 160 is formed on the base substrate 101 having the source metal patterns 141, 143, 144 and 155 formed thereon so that the transistor layer 103 is completed

Referring to FIGS. 4C, 5 and 6, the color organic layer is formed on the base substrate 101 having the transistor layer 103 formed thereon. The opening 175 is formed at the color filter layer 170 and the opening 175 has substantially the same shape as in the first embodiment. The capping layer 180 is formed on the color filter layer 170.

Referring to FIGS. 4D, 5 and 6, the capping layer 180 and the protecting layer 160 are etched to form the contact hole 165. A transparent conductive layer is formed on the base substrate 101 having the contact hole 165 formed thereon. The transparent conductive layer is patterned to form the pixel electrode 190 in the pixel area P (see FIG. 5). The pixel electrode 191 is formed spaced apart from the data line 141. The light-blocking layer 115 is formed under the data line 141 to block light leakage from the area between the pixel electrode 191 and the data line 141. Thus, the pixel electrode 191 may be formed to be spaced apart from the data line 141.

According to exemplary embodiments of the present invention described herein, the display substrate 100 has a structure omitting the storage common line or the storage electrode formed independently in the pixel area. Thus, the display substrate may improve light transmittance.

In addition, the light leaked from a stepped portion formed by the upper and left sides of the opening may be blocked using the contact part, and the light leaked from a stepped portion formed by the lower and right sides of the opening may be blocked using the blocking pattern of the opposing substrate. Thus, a size of the contact part may be reduced to improve light transmittance.

In addition, the light-blocking layer having the floating state is formed under the data line so that the capacitances between the pixel electrode and the data line and between the light-blocking layer and the data may be weak. For example, the display substrate having the light-blocking layer may be employed in large monitors which are greater than 24 inches.

Having described the exemplary embodiments of the present invention and their aspects, features and advantages, it is noted that various changes, substitutions and alterations can be made herein without departing from the spirit and scope of the present invention as defined by the appended claims.

What is claimed is:

1. A display substrate comprising:
a transistor layer including a transistor connected to a gate line and a data line crossing each other, and a contact part extending from a drain electrode of the transistor;
a color filter layer disposed on the transistor layer, the color filter layer having an opening therein, a center of the opening being spaced apart from a center of the contact part; and
a pixel electrode connected to the transistor through a contact hole exposing the contact part.

2. The display substrate of claim 1, wherein the pixel electrode is disposed on the transistor layer and overlaps the data line.

3. The display substrate of claim 1, wherein the transistor is adjacent to a portion at which the gate line crosses the data line, and the contact part is adjacent to the transistor.

4. The display substrate of claim 3, wherein each of the contact part and the opening comprises four sides, and
upper and left sides of the opening are spaced apart from upper and left sides of the contact part, so that the upper and left sides of the opening are partially overlapped with an area corresponding to the contact part.

5. The display substrate of claim 4, wherein lower and right sides of the opening are spaced apart from lower and right sides of the contact part, and are outside the area corresponding to the contact part.

6. The display substrate of claim 4, wherein the contact hole comprises four sides, and the contact hole is formed in an area in which the contact part overlaps the opening.

7. The display substrate of claim 6, wherein a distance between the left side of the opening and the left side of the contact part is about 2 μm to about 7 μm,
a distance between the left side of the opening and a left side of the contact hole is about 2 μm to about 7 μm,
each side of the contact hole has a length of about 4 μm to about 8 μm,
a distance between the right side of the opening part and a right side of the contact hole is about 4 μm to about 10 μm, and
a distance between the right side of the contact part and the right side of the contact hole is about 2 μm to about 5 μm.

8. The display substrate of claim 1, further comprising a light-blocking layer disposed under the data line, the light-blocking layer having a floating state.

9. The display substrate of claim 8, wherein the light-blocking layer is formed from the same layer as the gate line.

10. The display substrate of claim 8, wherein the pixel electrode is spaced apart from the data line.

11. A display panel comprising:
a display substrate including:
a transistor layer including a transistor connected to a gate line and a data line crossing the gate line, and a contact part extending from a drain electrode of the transistor;
a color filter layer disposed on the transistor layer, the color filter layer having an opening, a center of the opening being spaced apart from a center of the contact part; and
a pixel electrode connected to the transistor through a contact hole exposing other contact part; and
an opposing substrate coupling with the display substrate to receive a liquid crystal layer therebetween, the opposing substrate including a common electrode.

12. The display panel of claim 11, wherein the liquid crystal layer includes liquid crystal having a high driving voltage and a low dielectric anisotropy.

13. The display panel of claim 11, wherein the pixel electrode is disposed on the transistor layer to overlap the data line.

14. The display panel of claim 11, wherein the transistor is adjacent to an area in which the gate line crosses the data line, and the contact part is adjacent to the transistor.

15. The display panel of claim 14, wherein each of the contact part and the opening comprises four sides, and
upper and left sides of the opening are spaced apart from upper and left sides of the contact part, and the upper and left sides of the opening are partially overlapped with an area corresponding to the contact part.

16. The display panel of claim 15, wherein lower and right sides of the opening are spaced apart from lower and right sides of the contact part, and the lower and right sides of the opening are defined outside the area corresponding to the contact part.

17. The display panel of claim 16, wherein the contact hole comprises four sides, and the contact hole is formed in an area in which the contact part overlaps the opening.

18. The display substrate of claim 17, wherein a distance between the left side of the opening and the left side of the contact part is about 2 μm to about 7 μm,
a distance between the left side of the opening and a left side of the contact hole is about 2 μm to about 7 μm,
each side of the contact hole has a length of about 4 μm to about 8 μm,
a distance between the right side of the opening part and a right side of the contact hole is about 4 μm to about 10 μm, and
a distance between the right side of the contact part and the right side of the contact hole is about 2 μm to about 5 μm.

19. The display panel of claim 16, wherein the opposing substrate further includes a blocking pattern which blocks light, and
the blocking pattern exposes the upper and left sides of the contact part and covers the opening.

20. The display panel of claim 19, wherein the display substrate further includes a light-blocking layer disposed under the data line, and the light-blocking layer has a floating state.

21. The display panel of claim 20, wherein the light-blocking layer is formed from the same layer as the gate line.

22. The display panel of claim 19, wherein the pixel electrode is spaced apart from the data line.
